(19) United States
(12) Patent Application Publication
(10) Pub. No.: US 2026/0282583 A1
(43) Pub. Date: Sep. 17, 2026

(54) IMAGE SENSOR INCLUDING CONDUCTIVE PATTERN

(71) Applicant: Samsung Electronics Co., Ltd., Suwon-si (KR)

(72) Inventors: Hochul Ji, Suwon-si (KR); Sungin Kim, Suwon-si (KR)

(73) Assignee: Samsung Electronics Co., Ltd., Suwon-si (KR)

(21) Appl. No.: 19/546,264

(22) Filed: Feb. 20, 2026

(30) Foreign Application Priority Data
Mar. 12, 2025 (KR) 10-2025-0032067

(51) Int. Cl. H10F 39/00

(52) U.S. Cl. CPC H10F 39/807; H10F 39/8023; H10F 39/8037; H10F 39/811

(57) ABSTRACT

An image sensor according to example embodiments of the present disclosure includes: a substrate including pixel regions including each photodiode; a floating diffusion region disposed in each of the pixel regions, on one surface of the substrate; circuit elements transmitting a photoelectric signal according to the charges of the floating diffusion region; and an upper isolation pattern defining the floating diffusion region and the circuit elements on the one surface of the substrate, and at least one of the circuit elements includes: a gate pattern disposed on the one surface of the substrate; and a source/drain region disposed on both side surfaces of the gate pattern, and at least one of the source/drain regions includes a conductive layer disposed on the upper isolation pattern, contacting the substrate below the gate pattern, and including a material different from a material of the substrate.

### CROSS-REFERENCE TO RELATED APPLICATIONS

This present application claims priority to and the benefit under 35 U.S.C. § 119(a)-(d) of Korean Patent Application No. 10-2025-0032067 filed on Mar. 12, 2025, in the Korean Intellectual Property Office, the entire disclosure of which is incorporated herein by reference.

### FIELD

The present disclosure relates to an image sensor and more particularly to an image sensor including a conductive pattern.

### BACKGROUND

An image sensor is a semiconductor-based sensor that receives light and generates an electric signal, and may include a pixel array having a plurality of pixels, and a logic circuit for driving the pixel array and generating an image. Each of the pixels may include a photodiode, and a pixel circuit converting a charge generated by the photodiode into an electric signal. As the number of pixels included in the image sensor increases and the size of each pixel decreases, various methods have been proposed to effectively form components and contact plugs and an interconnection line, which are disposed in each pixel to provide a pixel circuit.

### SUMMARY

Aspects of the present disclosure provide an image sensor in which source/drain regions of a source follower transistor are stacked on a PD isolation pattern and then formed separately so as to maximize a gate electrode area of the source follower transistor.

Aspects of the present disclosure provide an image sensor in which noise is minimized by providing a conductive layer forming a separate source/drain region on a PD isolation pattern.

An image sensor according to example embodiments of the present disclosure includes: a substrate including pixel regions including each photodiode; a floating diffusion region disposed in each of the pixel regions and configured to store charges transferred from the photodiode, on one surface of the substrate; circuit elements transmitting a photoelectric signal according to the charges of the floating diffusion region; and an upper isolation pattern defining the floating diffusion region and the circuit elements on the one surface of the substrate, and at least one of the circuit elements includes: a gate pattern disposed on the one surface of the substrate; and a source/drain region disposed on both side surfaces of the gate pattern, and at least one of the source/drain regions includes a conductive layer disposed on the upper isolation pattern, contacting the substrate below the gate pattern, and including a material different from a material of the substrate.

Meanwhile, an image sensor according to example embodiments of the present disclosure includes: a substrate including pixel regions including each photodiode; a trench separation region defining the pixel regions within the substrate; a floating diffusion region configured to store charges transferred from the photodiode, on one surface of the substrate; a source follower transistor including a gate pattern disposed adjacently to the trench separation region and source/drain regions disposed on both sides of the gate pattern, and configured to transmit a signal by amplifying the charge of the floating diffusion region; and an upper isolation pattern disposed on the trench separation region on the one surface of the substrate and adjacent to the gate pattern of the source follower transistor, and at least one of the source/drain regions of the source follower transistor includes a semiconductor conductive layer disposed on the adjacent upper isolation pattern, overlapping the trench separation region in a vertical direction, and including a material different from a material of the substrate.

An image sensor according to example embodiments of the present disclosure includes: a pixel array including a plurality of pixel regions arranged in a direction parallel to one surface of a substrate, each of the plurality of pixel regions having at least one photodiode inside the substrate, a color filter disposed on the other surface of the substrate opposite to the one surface and at least one element disposed on the one surface; and a logic circuit obtaining a pixel signal from the plurality of pixel regions, and the pixel array includes: a floating diffusion region disposed on each of the plurality of pixel regions, and configured to store charges transferred from the photodiode, on the one surface of the substrate; circuit elements transmitting a photoelectric signal according to the charges of the floating diffusion region; and an upper isolation pattern defining the floating diffusion region and the circuit elements on the one surface of the substrate, and at least one of the circuit elements includes: a gate pattern disposed on the one surface of the substrate; and source/drain regions disposed on both side surfaces of the gate pattern, and at least one of the source/drain regions includes a conductive layer disposed on the upper isolation pattern, contacting the substrate below the gate pattern, and including a different material from the substrate.

Meanwhile, a method of manufacturing an image sensor according to example embodiments of the present disclosure includes: forming a lower isolation pattern defining pixel regions inside a substrate and an upper isolation pattern from one surface of the substrate on the lower isolation pattern; etching at least a portion of the upper isolation pattern on the one surface of the substrate to form a first opening; forming a conductive layer by filling a conductive material in the first opening; and forming a source follower transistor having a gate pattern on the one surface of the substrate as a source/drain region of the conductive layer.

In the forming a conductive layer, the conductive material may be filled in the first opening so as to protrude inwardly from an upper surface of the upper isolation pattern.

The method may further include planarizing the conductive material so that an upper surface of the conductive layer is coplanar with the one surface of the substrate.

A depth of the conductive layer may be shallower than a depth of the upper isolation pattern.

The method may further include, after forming the gate pattern, doping a first conductivity type impurity onto a gate spacer of the gate pattern and the conductive layer.

The method may further include, after doping the first conductivity type impurity, activating the impurity by annealing.

In the forming a conductive layer, polysilicon may be stacked as the conductive material.

The method of manufacturing the image sensor may further include forming a contact plug connected to the conductive layer.

An upper surface of the conductive layer may be formed to be disposed on a higher level than a level of the one surface of the substrate.

The conductive layer may be formed to be shared by the source/drain regions of at least two source follower transistors adjacent to one another.

According to example embodiments of the present disclosure, in order to maximize a gate electrode area of a source follower transistor, source/drain regions of the source follower transistor are separately formed on a PD isolation pattern to secure an area of the gate electrode and minimize noise.

By providing a conductive layer forming a separate source/drain region in a buried form after removing some of a PD isolation pattern, unnecessary capacitance may be minimized.

In various layouts, a conductive layer may be formed on a PD isolation pattern to share the source/drain region, thereby minimizing the number of contact plugs.

Advantages and effects of the present application are not limited to the foregoing content and may be more easily understood in the process of describing example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram simply illustrating an image sensor according to example embodiments of the present disclosure;

FIG. 2 is a circuit diagram simply illustrating a pixel circuit according to example embodiments of the present disclosure.

FIG. 3 is a diagram simply illustrating an arrangement of pixels of the image sensor of FIG. 2;

FIG. 4 is a cross-sectional view illustrating the image sensor of FIG. 3;

FIG. 5 is an enlarged view of a portion of FIG. 4;

FIG. 6, FIG. 7, FIG. 8, FIG. 9, FIG. 10 and FIG. 11 are enlarged views of an image sensor according to example embodiments of the present disclosure;

FIG. 12 is a circuit diagram simply illustrating a pixel circuit according to example embodiments of the present disclosure;

FIG. 13 and FIG. 14 are layout diagrams of an image sensor according to example embodiments of the present disclosure;

FIG. 15 is a cross-sectional view of an image sensor according to example embodiments of the present disclosure; and

FIG. 16A, FIG. 16B, FIG. 16C, FIG. 16D, FIG. 16E, FIG. 16F and FIG. 16G are cross-sectional views illustrating a method of manufacturing the image sensor of FIG. 4.

### DETAILED DESCRIPTION

Hereinafter, example embodiments of the present disclosure will be described with reference to the accompanying drawings.

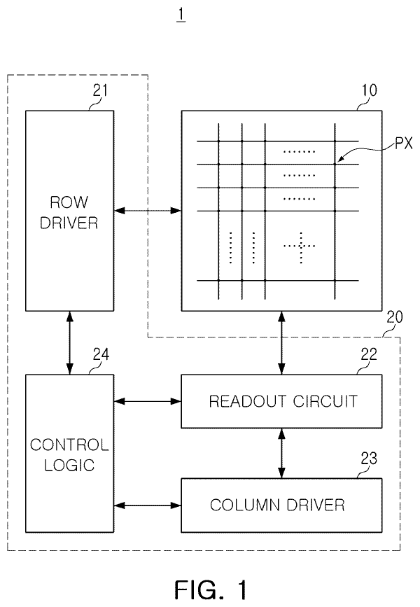

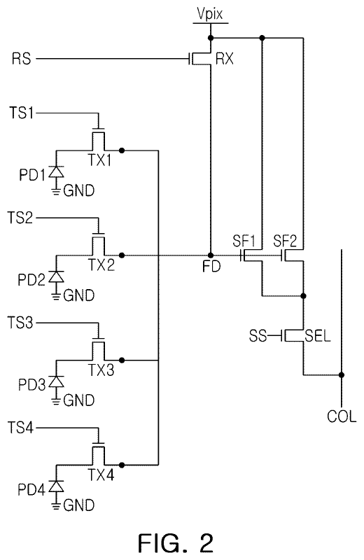

FIG. 1 is a block diagram simply illustrating an image sensor according to example embodiments of the present disclosure.

Referring to FIG. 1, an image sensor 1 may include a pixel array 10 and a logic circuit 20.

The pixel array 10 may include a plurality of pixels PX arranged in an array form along a plurality of rows and a plurality of columns. Each of the plurality of pixels PX may include at least one photoelectric conversion element generating charges in response to light, and a pixel circuit generating a pixel signal corresponding to the charges generated by the photoelectric conversion element. The photoelectric conversion element may include a photodiode formed of a semiconductor material, and/or an organic photodiode formed of an organic material.

For example, the pixel circuit may include a floating diffusion region, a transfer transistor, a reset transistor, a source follower transistor, and a selection transistor, etc. The components of the pixels PX may vary according to example embodiments. For example, each of the pixels PX may include an organic photodiode including an organic material, or may be implemented as a digital pixel. When the pixels PX are implemented as digital pixels, each of the pixels PX may include an analog-to-digital converter for outputting a digital pixel signal.

The logic circuit 20 may include circuits for controlling the pixel array 10. For example, the logic circuit 20 may include a row driver 21, a readout circuit 22, a column driver 23, and a control logic 24. The row driver 21 may drive the pixel array 10 in units of row lines. For example, the row driver 21 may generate a transmission control signal for controlling a transfer transistor of the pixel circuit, a reset control signal for controlling a reset transistor, a selection control signal for controlling a selection transistor, and the like, and input these signals to the pixel array 10 in units of row lines.

The readout circuit 22 may include a correlated double sampler (CDS), and an analog-to-digital converter (ADC). The correlated dual samplers may be connected through the pixels PX and the column lines. The correlated dual samplers may read the pixel signal from the pixels PX connected to a low line selected by the low line selection signal of the row driver 21 through the column lines. The analog-to-digital converter may convert the pixel signal detected by the correlated dual sampler into a digital pixel signal and transmit the signal to the column driver 23.

The column driver 23 may include a latch or a buffer circuit and an amplifier circuit that may temporarily store the digital pixel signal, and may process the digital pixel signal received from the readout circuit 22. The row driver 21, the readout circuit 22, and the column driver 23 may be controlled by the control logic 24. The control logic 24 may include a timing controller for controlling the operation timing of the row driver 21, the readout circuit 22, and the column driver 23.

Among the pixels PX, pixels PX disposed in the same position in a horizontal direction may share the same column line. For example, pixels PX disposed in the same position in a vertical direction may be simultaneously selected by the row driver 21 and may output a pixel signal through the column lines. In example embodiments, the readout circuit 22 may simultaneously obtain pixel signals from pixels PX selected by the row driver 21 through the column lines. The pixel signal may include a reset voltage and a pixel voltage, and the pixel voltage may be a voltage in which charges generated in response to light in each of the pixels PX are reflected in the reset voltage.

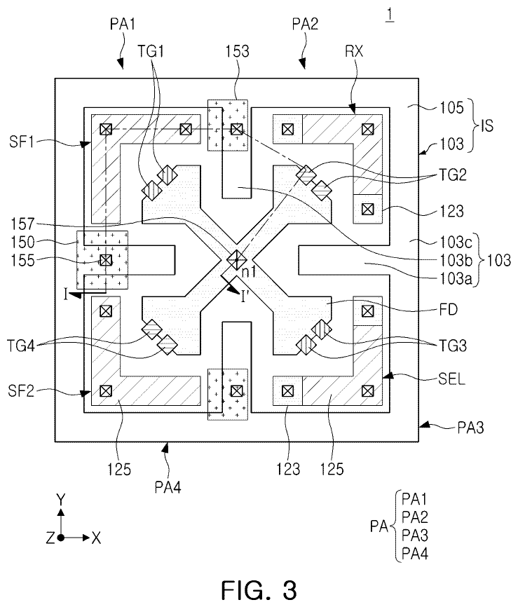

FIG. 2 is a circuit diagram simply illustrating a pixel circuit according to example embodiments of the present disclosure, and FIG. 3 is a view simply illustrating an arrangement of pixels of the image sensor of FIG. 2.

Referring to FIG. 2, each of the plurality of pixels PX (see FIG. 1) may include a photodiode and a transfer transistor TX. The image sensor may include pixel circuits having a reset transistor RX, a selection transistor SEL, and a source follower transistor SF. In addition, the pixel circuit may further include a floating diffusion region FD in which charges generated by the photoelectric conversion element are accumulated.

Photodiodes PD1, PD2, PD3, and PD4 may generate and accumulate charges in response to externally incident light. The photodiodes PD1, PD2, PD3, and PD4 may be replaced with phototransistors, photogates, pinned photodiodes, and the like, according to example embodiments.

Transfer transistors TX1, TX2, TX3, and TX4 may be turned on or off by a transfer signal input to transfer transistors TX1, TX2, TX3, and TX4. The transfer transistors TX1, TX2, TX3, and TX4 may transfer the charges generated by the photodiodes PD1, PD2, PD3, and PD4 to the floating diffusion region FD. The floating diffusion region FD may store the charge generated by the photodiodes PD1, PD2, PD3, and PD4. A voltage output by the source follower transistors SF1, SF2 may vary depending on the amount of charge accumulated in the floating diffusion region FD.

The reset transistor RX may reset a voltage of the floating diffusion region FD by removing the charges accumulated in the floating diffusion region FD. A drain electrode of the reset transistor RX may be connected to the floating diffusion region FD, and a source electrode may be connected to a power supply voltage Vpix. When the reset transistor RX is turned on, the power supply voltage Vpix connected to the source electrode of the reset transistor RX may be applied to the floating diffusion region FD, and the reset transistor RX may remove the charges accumulated in the floating diffusion region FD.

Source follower transistors SF1 and SF2 may operate as source follower buffer amplifiers. The source follower transistors SF1 and SF2 may amplify a voltage change of the floating diffusion region FD and output the voltage to column lines COL.

The selection transistor SEL may select the pixels PX to be read in units of columns, among the plurality of pixels PX. When the selection transistor SEL is turned on, the voltage of the source follower transistor SF may be output to the column lines COL. For example, when the selection transistor SEL is turned on, a reset voltage or a pixel voltage may be output through the column lines COL.

The reset transistor RX may be controlled by a reset control signal RS, and the selection transistor SEL may be controlled by a selection control signal SS. The first to fourth transfer transistors TX1 to TX4 may be controlled by a first or second bias voltage, which is transmission signals TS1 to TS4.

Each of the pixels PX may further include a ground region GND that may receive a ground voltage. Accordingly, each of the pixels PX may include a ground region GND, photodiodes PD1, PD2, PD3, and PD4, transfer transistors TX1, TX2, TX3, and TX4, a reset transistor RX, a selection transistor SEL, and source follower transistors SF1 and SF2, and each of the elements may be disposed to be divided into a plurality of elements connected in parallel. For example, the first to fourth photodiodes PD1, PD2, PD3, and PD4 may be connected to the first to fourth transfer transistors TX1, TX2, TX3, and TX4 and may be driven by the first and second source follower transistors SF1 and SF2.

Each of the pixels PX may be structured as one pixel region PA, and one pixel region PA may include four sub-pixel regions PA1 to PA4, as illustrated in FIG. 3. The four sub-pixel regions PA1 to PA4 may be disposed in a 2×2 array. The first sub-pixel region PA1 may include a first photodiode PD1, at least a portion of a floating diffusion region FD, and a first transfer gate TG1 having a first transfer transistor TX1. In the first pixel region PA1, the first photodiode PD1 may be connected to a common floating diffusion region FD through the first transfer gate TG1. Similarly, the second to fourth photodiodes PD2 to PD4 of the second to fourth sub-pixel regions PA2 to PA4 may be connected to the common floating diffusion region FD through second to fourth transfer gate TG2 to TG4, respectively.

In the four sub-pixel regions PA1 to PA4 adjacent to one another, the floating diffusion region FD may be defined as a single structure connected to one another and may also be referred to as a common diffusion region FD. The common diffusion region FD may be understood as a structure extending from a center n1 of the four sub-pixel regions PA1 to PA4 to each of the four sub-pixel regions PA1 to PA4. For example, as illustrated in FIG. 3, the common diffusion region FD includes four bar-type regions passing through the center n1 region of four sub-pixel regions PA1 to PA4, and extending to each of the four sub-pixel regions PA1 to PA4, and may include an expansion region in each end thereof.

The four sub-pixel regions PA1 to PA4 adjacent to one another may share a pixel circuit, and the shared pixel circuit may include a reset transistor RX, first and second source follower transistors SF1 and SF2, and a selection transistor SEL.

For example, each of the four sub-pixel regions PA1 to PA4 may include one more transistor in addition to the transfer gates TG1 and TG2. Two of the four transistors included in the four sub-pixel regions PA1 to PA4 may be connected in parallel to one another to provide the first and second source follower transistors SF1 and SF2, one of the remaining two transistors may be configured to provide the selection transistor SEL and the other there of may be configured to provide the reset transistor RX.

The pixel circuit described with reference to FIG. 2 is only example embodiments and is not necessarily limited to such a form. For example, one of the four transistors may be assigned as the source follower transistor SF, one thereof may be assigned as the selection transistor SEL, and the other thereof may be assigned as the reset transistor RX. In addition, the remaining one may be assigned as a dual conversion gain transistor DCG connected in series to the reset transistor RX to implement an image sensor 1 capable of controlling a conversion gain of a pixel. Alternatively, the pixel circuit may vary depending on the number of transistors included in each of the pixels PX.

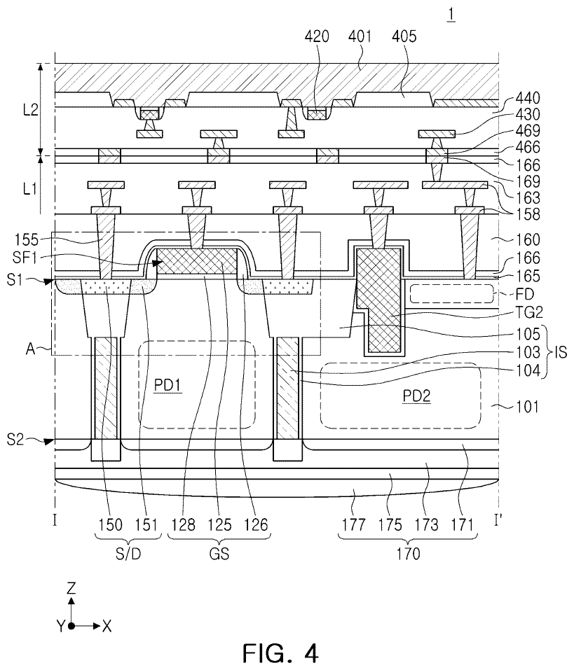

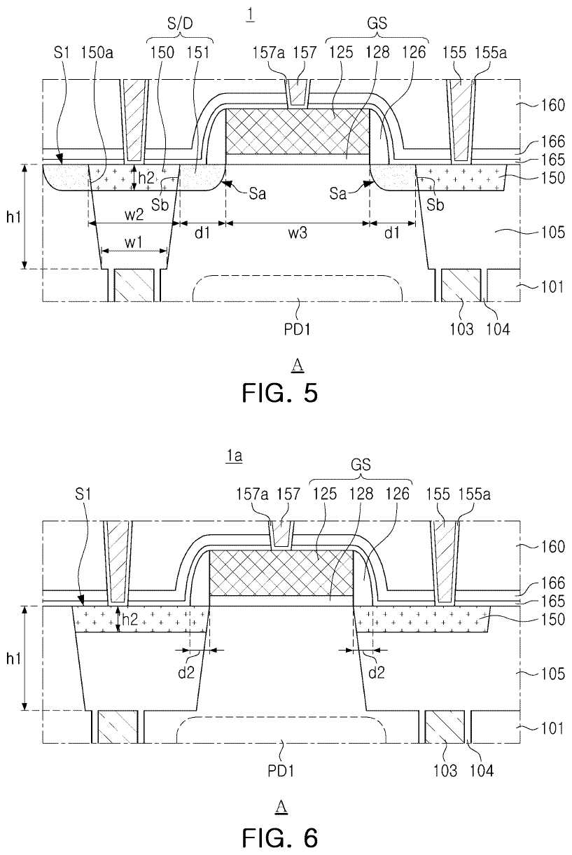

In FIG. 3, the image sensor 1 is a top view of a region corresponding to one pixel PX of the pixel array 10 on a substrate 101, and FIG. 4 is a cross-sectional view illustrating a cross-section of one of the pixels of FIG. 3. FIG. 4 is a cross-sectional view along the cutting line I-I′ of FIG. 3, and FIG. 5 is an enlarged view of region “A” of FIG. 4.

The image sensor 1 may include a first structure L1 corresponding to the pixel array 10 and a second structure L2 corresponding to the logic circuit 20 bonded thereto.

In the pixel array 10, pixel regions PA corresponding to the pixels PX include sub-pixel regions PA1 to PA4 in a 2×2 array. The pixel regions PA or sub-pixel regions PA1 to PA4 may include all of the photodiodes PD1, PD2, PD3, and PD4, active regions 123 and ground regions GND included within the substrate 101, and the pixel region PA may be defined as a region in which elements for operating as one pixel PX of FIG. 2 are disposed, and the sub-pixel regions PA1 to PA4 may be defined as regions partitioned by a first isolation pattern 103 within the pixel region PA.

Accordingly, the first isolation pattern 103 is disposed between the sub-pixel regions PA1 to PA4 and between the pixel regions PA. The first isolation pattern 103 may be arranged in a lattice shape within the substrate 101, and may include a first trench separation film 103c defining each pixel region PA and second trench separation films 103a and 103b defining the sub-pixel regions PA1 to PA4.

When viewed from above, the first trench separation film 103c may extend in an X-direction and a Y-direction to define each pixel region PA, and may be disposed so as to partition a rectangle, specifically, a rectangular or square space inside. The second trench separation films 103a and 103b may be a bar type structure protruding from the inside of the first trench separation film 103c toward the center nl so as to partition each of the sub-pixel regions PA1 to PA4, when viewed from above. For example, the second trench separation films 103a and 103b may include a second-first trench separation film 103a extending in the X-direction and a second-second trench separation film 103b extending in the Y-direction.

The second-first trench separation film 103a and the second-second trench separation film 103b may have a structure in which one end thereof is cut to expose the center n1 within one pixel region PA. The common floating diffusion region FD may be disposed from the center n1 in which the second-first trench separation film 103a and the second-second trench separation film 103b are separated.

The first isolation pattern 103 is a vertical structure extending from one surface S1 of the substrate 101 to the other surface S2, and may partition each pixel region PA or sub-pixel region PA1 to PA4 by intersecting the substrate 101 in a vertical direction.

The first to fourth sub-pixel regions PA1 to PA4 may have substantially the same area, and circuit elements may be disposed symmetrically with respect to the center n1 of the pixel region PA.

Each of the first to fourth sub-pixel regions PA1 to PA4 may include one transistor among the circuit elements, at least one transfer gates TG1 to TG4, and a portion of the common floating diffusion region FD. A ground region (not illustrated) may be disposed in at least a portion of each sub-pixel region PA1 to PA4.

The common floating diffusion region FD within the first to fourth sub-pixel regions PA1 to PA4 is a region doped with a first conductivity type impurity, and may be a region in which charges generated by the photodiodes PD1, PD2, PD3, and PD4 are accumulated. For example, the first conductivity type impurity may be an N-type impurity. The first conductivity type impurity may be As or P, and may be doped at a concentration of, for example, 1×10¹⁶ to 1×10¹⁸/cm³.

The common floating diffusion region FD may be electrically connected to at least one contact plug 157, and one end of the common floating diffusion region FD may be adjacent to each of the first to fourth transfer gates TG1, TG2, TG3, and TG4. The first to fourth transfer gates TG1, TG2, TG3, and TG4 may be adjacent to the first to fourth photodiodes PD1, PD2, PD3, and PD4 formed on an inner side of the first isolation pattern 103 in the first direction (Z-direction, vertical direction).

When a first bias voltage is input to the first to fourth transfer gates TG1, TG2, TG3, and TG4, charges generated by the first to fourth photodiodes PD1, PD2, PD3, and PD4 may not move to the common floating diffusion region FD. When a voltage of the first to fourth transfer gates TG1, TG2, TG3, and TG4 increases to a second bias voltage higher than the first bias voltage, the charges generated by the first to fourth photodiodes PD1, PD2, PD3, and PD4 may move to the common floating diffusion region FD. For example, the first bias voltage may be a negative voltage, and the second bias voltage may be a positive voltage. An absolute value of the first bias voltage may be smaller than an absolute value of the second bias voltage.

In example embodiments illustrated in FIG. 3, a first transfer gate TG1 connected to a first photodiode PD1 may be disposed in a first sub-pixel region PA1, and a second transfer gate TG2 connected to a second photodiode PD2 may be disposed in a second sub-pixel region PA2. A third transfer t gates TG3 connected to a third photodiode PD3 may be disposed in a third sub-pixel region PA3, and a fourth transfer gates TG4 connected to a fourth photodiode PD4 may be disposed in a fourth sub-pixel region PA4.

In the first to fourth sub-pixel regions PA1 to PA4, one transistor of the reset transistor RX, the selection transistor SEL and the source follower transistors SF1 and SF2, among the transistors that are circuit elements, may be disposed, respectively. For example, the first and second source follower transistors SF1 and SF2 may be disposed in the first sub-pixel region PA1 and the fourth sub-pixel region PA4, respectively, and the reset transistor RX may be disposed in the second sub-pixel region PA2, and the selection transistor SEL may be disposed in the third sub-pixel region PA3.

Each of the transistors that are circuit elements may include a gate pattern GS, and active regions 123 disposed on both sides of the gate pattern GS. An area of each of the active regions 123 may be smaller than an area of the common floating diffusion region FD. This may be because an area of the common floating diffusion region FD in which the charges generated by the respective photodiodes PD1, PD2, PD3, and PD4 are accumulated should be secured relatively larger.

The first structure L1 may further include a second isolation pattern 105 for separating the active regions 123 and the common floating diffusion region FD from one surface S1 of the substrate 101.

Among the transistors that are circuit elements, the source follower transistors SF1 and SF2 may have a gate pattern GS greater than the gate pattern GS of other transistors, for example, the reset transistor RX or the selection transistor SEL. Here, being greater does not mean a height, but may mean an area, that is, the area occupied by a gate electrode 125 on the substrate 101.

The source follower transistors SF1 and SF2 are source follower buffer amplifiers, and as a size of the gate pattern GS increases, the noise of an output signal may be reduced. For this purpose, the area of the gate pattern GS of the source follower transistors SF1 and SF2 may be designed to be greater than that of the gate patterns GS of the other transistors, which may lead to an increase in a channel length.

For this purpose, a source region and/or drain region (S/D) of the source follower transistors SF1 and SF2 may be implemented as a semiconductor conductive layer 150 having a different material from the substrate 101.

The source region and/or drain region (S/D) includes a conductive layer 150, and the conductive layer 150 may be disposed on the second-first and/or second-second trench separation films 103a and 103b so as to overlap at least a portion of the second-first and/or second-second trench separation films 103a and 103b in a Z-direction. Accordingly, the active region 123 of the source follower transistors SF1 and SF2 is not disposed in the first and fourth sub-pixel regions PA1 to PA4, so that an area available as the gate pattern GS may increase.

Meanwhile, the sub-pixel regions PA1 to PA4 may further include an active region for a ground region. The ground region may be separated from the common floating diffusion region FD and the transistors, and may not be in contact with the transfer gates TG1 to TG4. In addition, the ground region may be doped with a second conductivity type impurity different from the common floating diffusion region FD and the active regions 123.

The contact plugs 157 may be disposed in the first to fourth transfer gates TG1 to TG4, the common floating diffusion region FD, the gate patterns GS, the active regions 123 and the ground region.

Describing in detail with reference to FIG. 4 and FIG. 5, the substrate 101 may be a semiconductor substrate. For example, the substrate 101 may be a substrate 101 formed of a semiconductor material, for example, a single crystal silicon substrate. The substrate 101 may include one surface S1 on which the gate patterns GS of the circuit elements are disposed, and the active regions 123, the common floating diffusion region FD and the second isolation pattern 105 are formed, and the other surface S2 opposite thereto.

The respective photodiodes PD1, PD2, PD3, and PD4 may be formed in the substrate 101 within the four sub-pixel regions PA1 to PA4. The photodiodes PD1, PD2, PD3, and PD4 may include a first conductivity type impurity, and may include, for example, an N-type impurity. The photodiodes PD1, PD2, PD3, and PD4 may be adjacent to the respective transfer gates TG1, TG2, TG3, and TG4 in the Z-direction, perpendicular to one surface S1 of the substrate 101.

Meanwhile, an optical unit 170 may be disposed on the other surface S2 of the substrate 101, adjacent to the photodiodes PD1, PD2, PD3, and PD4 in the Z-direction, the vertical direction. The optical unit 170 may include a color filter 171, a grid 173, a planarization layer 175, and a micro lens 177. The color filter 171 may be separated from a color filter of another adjacent pixel by the grid 173 and may transmit light of a predetermined wavelength band. The micro lens 177 may refract light incident on the pixel PX and focus the light onto the photodiodes PD1, PD2, PD3, and PD4. The photodiodes PD1, PD2, PD3, and PD4 may generate the charges in response to light passing through the optical unit 170.

Accordingly, the optical unit 170 and circuit elements may be disposed on both sides of the photodiodes PD1, PD2, PD3, and PD4 in the Z-direction.

The first and second trench separation films 103a, 103b and 103c separating the photodiodes PD1, PD2, PD3, and PD4 in the substrate 101, respectively, and partitioning the sub-pixel regions PA1 to PA4 may be disposed in a grid shape and a bar shape extending from the grid shape toward the center nl of each pixel region PA in the substrate 101. The first isolation pattern 103 may include a conductive material, for example, a semiconductor material, in a central region, and may include a semiconductor material including an impurity of a second conductivity type different from the first conductivity type.

A liner may be disposed by surrounding the conductive material, and a trench insulating layer 104 may be disposed between the liner and the substrate 101. Accordingly, a conductive material in the first isolation pattern 103 may be electrically insulated from the substrate 101. In the case in which the conductive material is included in the first isolation pattern 103, when a black current flows, the charge collection capability of the photodiodes PD1, PD2, PD3, and PD4 may be improved. A substrate insulating region may be further included between the photodiodes PD1, PD2, PD3, and PD4 and the trench insulating layer 104, but the present disclosure is not limited thereto.

A second isolation pattern 105 (STI) defining the active regions 123 of the circuit elements and the common floating diffusion region FD inside the substrate 101 may be disposed on one surface S1 of the substrate 101.

The second isolation pattern 105 may be formed by removing the entire one surface S1 of the substrate 101 by a first depth h1 except for a region in which the active regions 123 of the circuit elements are disposed and a region in which the common floating diffusion region FD is disposed, and then stacking an insulating material thereon.

The second isolation pattern 105 may also be disposed on the first isolation pattern 103. As illustrated in FIG. 4, the second isolation pattern 105 on the first isolation pattern 103 may be aligned in the Z-direction to form an PD isolation pattern IS partitioning each pixel region PA, and the PD isolation pattern IS may also partition the sub-pixel regions PA1 to PA4. The second isolation pattern 105 on the first isolation pattern 103 may be disposed to have a width greater than a width of the first isolation pattern 103, and may have a lower width W1 greater than a width of an upper portion of the first isolation pattern 103.

An upper surface of the second isolation pattern 105 may be substantially coplanar with one surface S1 of the substrate 101, but the present disclosure is not limited thereto, and at least portion of the upper surface of the second isolation pattern 105 may also be positioned at the same level of an upper surface of a gate insulating layer 128.

The second isolation pattern 105 may have a width that decreases from an upper surface to a lower surface, and thus may have an inclined side surface. The second isolation pattern 105 may include a liner surrounding the side surface and the lower surface, and an insulating material disposed on the liner and filled a trench. The insulating material may be a material such as a silicon oxide film, a silicon oxynitride film, or a silicon oxycarbonate film. In this case, in the PD isolation pattern IS in which the second isolation pattern 105 and the first isolation pattern 103 extend in the Z-direction, the liner may not be disposed on a bottom surface of the second isolation pattern 105 in contact with the upper portion of the first isolation pattern 103. When the second isolation pattern 105 is formed along the first isolation pattern 103, the second isolation pattern 105 may include a lattice shape.

The common floating diffusion region FD may be formed to include a first conductivity type impurity from one surface S1 of the substrate 101 by a predetermined depth. As described above, the common floating diffusion region FD may include bar-type regions extending from the center nl of the pixel region PA to the four sub-pixel regions PA1 to PA4, and one end of the bar-type region may be disposed to include an expansion region disposed within each of the sub-pixel regions PA1 to PA4.

The expansion region may have various shapes, and for example, may have a circular, oval, or polygonal shape. The transfer gates TG1, TG2, TG3, and TG4 of the transfer transistors TX may be disposed close to a portion of the expansion region.

Each of the transfer transistors TX1, TX2, TX3, and TX4 may include at least one of sub-transfer gates separated, and for example, may be a dual vertical transfer gates having two sub-transfer gates as illustrated in FIG. 3. Each of the sub-transfer gates may have the same structure, but the present disclosure is not limited thereto. Each of the sub-transfer gates may be disposed adjacently to the common floating diffusion region FD and may be connected in parallel with one another. The sub-transfer gates may include the same material as the gate electrode 125 of the circuit elements, and may be formed of a conductive material such as polysilicon, metal, or metal silicide, and the first bias voltage and the second bias voltage described above may be applied to the transfer gates TG1 to TG4. The gate insulating layer 128 and a gate spacer 126, and the like, may be disposed on the transfer gate TG. The gate insulating layer 128 may be disposed between the transfer gates TG1, TG2, TG3, and TG4 and the substrate 101.

The transfer gates TG1, TG2, TG3, and TG4 may include a first electrode layer and a second electrode layer, and the first electrode layer and the second electrode layer may have different shapes. For example, the second electrode layer may be disposed between the first electrode layer and the photodiodes PD1, PD2, PD3, and PD4 in the Z-direction, and may have a width that becomes narrower toward the photodiodes PD1, PD2, PD3, and PD4. The second electrode layer may be disposed below one surface S1 of the substrate 101 and may be buried in the substrate 101, and the first electrode layer may have a region disposed above one surface S1 of the substrate 101.

The gate insulating layer 128 may be formed along an interface between the transfer gates TG1, TG2, TG3, and TG4 and the substrate 101. The first electrode layer and the second electrode layer may be offset from one another in a horizontal direction and may be disposed in different positions. Accordingly, at least a portion of a lower surface of the first electrode layer may not be in direct contact with an upper surface of the second electrode layer, and at least a partial region of the gate insulating layer 128 may be disposed between the second isolation pattern 105 and the first electrode layer in the Z-direction.

Transistors that are circuit elements may include active regions 123 as a gate pattern GS and a source/drain region (S/D). The gate pattern GS may include a gate electrode 125, a gate insulating layer 128 and a gate spacer 126. The gate electrode 125 may be disposed above the surface S1 of the substrate 101 and may have a height corresponding to the first electrode layer of the transfer gates TG1 to TG4, but the present disclosure is not limited thereto. As illustrated in FIG. 3, the gate electrode 125 may be disposed at a corner, within respective sub-pixel regions PX1 to PX4 and may thus have a shape bent in the X-direction and the Y-direction. That is, the gate electrode 125 may have a shape extending in the Y-direction and then bent at the corner and extending in the X-direction. In this case, the gate electrode 125 may be disposed close to the PD isolation pattern IS on one surface S1 of the substrate 101, and when one end thereof is disposed close to the second-first trench separation film 103a, the other end thereof may be disposed close to the second-second trench separation film 103b. An area of the gate electrode 125 of the source follower transistors SF1 and SF2 may be greater than an area of the gate electrode 125 of the other transistors. Specifically, an extension length of the gate electrode 125 of the source follower transistors SF1 and SF2 in each direction may be greater than an extension length of the gate electrode 125 of the other transistors in each direction. However, a height of the gate electrode 125 of the source follower transistors SF1 and SF2 may be substantially identical to a height of the gate electrode 125 of the other transistors.

The gate electrode 125 of the circuit element may include a semiconductor material, and may include, for example, silicon, germanium, or combinations thereof. The gate electrode 125 may include a layer doped with an N-type or a P-type, but may also include an undoped layer, unlike this.

The gate insulating layer 128 may be disposed between the gate electrode 125 of the circuit element and the substrate 101, and the gate spacer 126 may be formed of silicon nitride or the like and may be formed on a side surface of the gate electrode 125.

Specifically, in the source follower transistors SF1 and SF2, the gate spacer 126 may be disposed between the gate electrode 125 and the second isolation pattern 105 when viewed in plan view, and one surface S1 of the substrate 101 may not be exposed between the gate electrode 125 and the second isolation pattern 105 or may be exposed in a significantly small area. Specifically, the gate spacer 126 may be significantly smaller than an area of the active region 123 for the source/drain region (S/D) of other transistors.

The transistors of other circuit elements except for the source follower transistors SF1 and SF2 may have active regions 123 disposed on both sides of the gate pattern GS. The active region 123 may be formed by injecting a first conductivity type impurity by a predetermined depth in one surface S1 of the substrate 101.

The active region 123 may form the source/drain region (S/D) on one surface S1 of the substrate 101 around the gate pattern GS of the transistors of other circuit elements except for the source follower transistors SF1 and SF2, for example, the reset transistor RX and/or the selection transistor SEL.

The source follower transistors SF1 and SF2, i.e., the circuit elements disposed in the first and fourth sub-pixel regions PA1 and PA4 may include a large gate pattern GS, and may have a conductive layer 150 that is adjacent to both sides of the gate pattern GS and forms the source region and the drain region (S/D).

The source/drain region (S/D) of the source follower transistors SF1 and SF2 may include the conductive layer 150 and a conductive region 151.

The conductive layer 150 of the source/drain region (S/D) of the source follower transistors SF1 and SF2 may overlap the first isolation pattern 103 in a vertical direction and may be disposed on the PD isolation pattern IS, and may include a different material from the substrate 101.

The conductive layer 150 may occupy most of the area of the source/drain region (S/D) and may be disposed on the second isolation pattern 105. Being disposed on the second isolation pattern 105 may denote including an upper surface disposed on the same level as one surface S1 of the substrate 101 and a lower surface protruding from the upper surface to the second isolation pattern 105 and contacting the upper surface of the second isolation pattern 105, and a vertical distance between the upper surface and the lower surface may have a second depth h2 smaller than the first depth h1 of the second isolation pattern 105. The second depth h2 may be smaller than or equal to the depth of the common floating diffusion region FD.

Accordingly, an upper surface of the conductive layer 150 may be coplanar with one surface S1 of the substrate 101, but is not limited thereto, and may be disposed on a higher level than the upper surface of the second isolation pattern 105. A width W2 of an upper portion of the conductive layer 150 may be greater than a width W1 of a lower portion of the second isolation pattern 105 and may have an inclined side surface so as to have a continuous inclination with the side surface of the second isolation pattern 105. Accordingly, it may be understood that when the conductive layer 150 protrudes into the second isolation pattern 105, the second isolation pattern 105 is removed by the width W2 and the conductive layer 150 is formed.

When viewed in plan view, the conductive layer 150 may have a rectangular shape, and a length of a side facing the gate electrode 125 may be greater than a width of the gate electrode 125.

The conductive layer 150 may include a conductive material, and may include, for example, a semiconductor material, and may include a semiconductor material including a first conductivity type impurity, such as polysilicon. Preferably, the conductive layer 150 may include an N-type impurity, and may include impurities such as As or P. In this case, the conductive layer 150 may include the same impurity as the impurity of other active regions 123, but is not limited thereto, and may include at least an impurity of the same conductivity type as the impurity of other active regions 123.

The conductive region 151 may be disposed within one surface S1 of the substrate 101 extending with the conductive layer 150.

The conductive region 151 may include a region of the substrate 101 below the gate spacer 126, and may be defined as the region of the substrate 101 between the gate electrode 125 and the conductive layer 150 when viewed in plan view.

One side of the conductive region 151 may be in contact with the conductive layer 150, and the other side thereof may be in contact with the channel region of the source follower transistors SF1 and SF2, and one side Sb of the conductive region 151 may have a continuous inclination, and the other side Sa may have a discontinuous inclination and may include a curved surface having an inflection point. That is, the shapes of both sides of the conductive region 151 may be different from one another.

The conductive region 151 may be formed by injecting the first conductivity type impurity from one surface S1 of the substrate 101 by a predetermined depth, and may have a curved surface at the other side Sa depending on the diffusion of the first conductivity type impurity. That is, the first conductivity type impurity may be doped in a state in which the gate spacer 126 is present, and a doping depth may vary inversely proportional to a thickness of the gate spacer 126. A length d1 of the conductive region 151 may be equal to or greater than a width of a lower surface of the gate spacer 126, and in the same case, one surface S1 of the substrate 101 may not be exposed between the conductive layer 150 and a conductive layer 150 on an opposite side.

The conductive layer 150 and the conductive region 151 may form a coplanar surface with one surface S1 of the substrate 101, and a maximum length of a thickness of the conductive region 151 may be substantially equal to the second depth h2 of the conductive layer 150, but the present disclosure is not limited thereto.

The first conductivity type impurities included in the conductive region 151 and the conductive layer 150 may be the same, and concentrations thereof may also be the same. One source follower transistor TG1 may have a structure in which, when viewed in plan view, the conductive region 151 is disposed on both sides of the gate electrode 125, and the conductive layer 150 is disposed on the outside of the conductive region 151.

Accordingly, a distance between the conductive regions 151 may be equal to a length W3 of the gate electrode 125, and may be smaller than a distance between the conductive layers 150. That is, each of the source/drain regions (S/D) on both sides of the gate electrode 125 may include the conductive region 151 and the conductive layer 150, and may function as a transistor by having a channel region between two conductive regions 151 on one surface S1 of the substrate 101 below the gate electrode 125.

When the conductive layer 150 includes a semiconductor material, the conductive layer 150 may have a single crystal structure 151a from a boundary between the conductive layer 150 and the conductive region 151. That is, crystallization may proceed from the single crystal structure of the silicon substrate 101 to have a portion of a single crystal structure 150a, and may have a polycrystal structure in a center of the conductive layer 150. Accordingly, the contact resistance may be minimized by having a crystal structure similar to that of the substrate 101 in the contact region between the conductive region 151 and the conductive layer 150.

In this manner, the source/drain region (S/D) may not be formed by doping one surface S1 of the substrate 101, but may be disposed on the second isolation pattern 105, so that areas of the sub-pixel region PA1 and PA4 that may be utilized as the source follower transistors SF1 and SF2 may be secured.

In addition, when each of the first sub-pixel region and the fourth sub-pixel region PA1 and PA4 includes source follower transistors SF1 and SF2, the two source follower transistors SF1 and SF2 connected in parallel to one another in FIG. 2 may share the conductive layer 150 disposed on one end, that, the second-first isolation pattern 103a, and may have the source/drain region (S/D) disposed therein, and only the conductive region 151 may be disposed below each gate spacer 126 within each sub-pixel region PA1 and PA4, so that an area of the gate electrode 125 within the pixel region PA may be maximally secured.

In addition, the number of contact plugs 155 may also be significantly reduced by disposing one contact plug 155 on the shared conductive layer 150 according to the connection relationship between the two transistors SF1 and SF2.

Areas of the source region and drain region (S/D) in the source follower transistors SF1 and SF2 may be identical to one another, but the present disclosure is not limited thereto, and widths of the conductive regions 151 of the two regions, i.e., widths dl of lower portions of the gate spacers 126, may identical to one another, but the conductive layers 150 of the two regions may vary depending on the width of the PD isolation pattern IS.

In FIG. 3, only the source follower transistors SF1 and SF2 are illustrated as having a source/drain region (S/D) including a conductive layer 150 and a conductive region 151, but according to example embodiments, in transistors that are other circuit elements, some source regions or drain regions (S/D) may also include the conductive layer 150.

For example, in the case of a reset transistor RX connected to the source follower transistors SF1 and SF2 according to the connection of circuit elements, the conductive layer 150 may be included to be shared with the source follower transistors SF1 and SF2, and the conductive region 151 may be included below the gate electrode 125 of the reset transistor RX.

On the other hand, in the case in which the source/drain region (S/D) is not shared with an adjacent transistor, the source/drain region (S/D) has the conductive region 151 is disposed on one side of a conductive layer 153 and has a non-shared structure on the other side of a conductive layer 153 without the conductive region 151, and the second isolation pattern 105 is continuous on the other side without the conductive region 151 In the case of the non-shared conductive layer 153, the source region or drain region (S/D) of the transistor disposed on the other side may be disposed so that the conductive region 151 formed by doping the first conductivity type impurity on one surface S1 of the substrate 101 is separated from the non-shared conductive layer 153 with the second isolation pattern 105 interposed therebetween. Accordingly, two transistors adjacent to the non-shared conductive layer 153 may be physically separated and electrically insulated from one another.

A substrate insulating layer 165 and an upper insulating layer 166 may be arranged to cover the conductive layer 150 and the gate pattern GS, and an interlayer insulating layer 160 may be disposed thereon.

In order to electrically connect an integrated floating diffusion region FD, the source/drain region (S/D) and the gate electrodes 125, the contact plugs 155 and 157 may be disposed to be connected to upper surfaces of the integrated floating diffusion region FD, the source/drain region (S/D) and the gate electrodes 125 by penetrating through the substrate insulating layer 165, the upper insulating layer 166 and the interlayer insulating layer 160. Specifically, in the case of the source/drain region (S/D) having the conductive layer 150, the contact plug 155 is disposed on the conductive layer 150 rather than the conductive region 151, as described above.

Accordingly, it may be understood that the contact plug 155 may be physically separated from the conductive region 151, but may electrically indirectly connected through the conductive layer 150.

The contact plugs 155 and 157 may be formed by having diffusion barriers 155a and 157a disposed on a side surface and a bottom surface, and filling a metal material on the diffusion barriers 155a and 157a.

The diffusion barriers 155a and 157a may be TiN, TaN, or the like, and the contact plugs 155 and 157 may include conductive materials such as W, Al, Cu, or the like.

Accordingly, since the source/drain region (S/D) is not formed on one surface S1 of the substrate 101, the contact plugs 155 and 157 may not be directly connected to the substrate 101, and thus, when forming the contact plugs 155 and 157, damage to the semiconductor substrate 101 may be minimized, and the number of contact plugs 155 and 157 may also be minimized.

The substrate insulating layer 165 may be conformally formed on one surface S1 of the substrate 101. The substrate insulating layer 165 may conformally cover lower gate patterns GS and the transfer gate TG in a lower portion and the substrate 101 on the gate patterns GS and the transfer gate TG. The substrate insulating layer 165 may include silicon oxide or a low-k dielectric material.

The substrate insulating layer 165 may be disposed to conformally cover the gate patterns GS and the transfer gates TG of each circuit element, for example, a transfer gate TG, the reset gate electrode, the selection gate electrode, the spacers 126 of the driving gate electrodes 125 and the exposed substrate 101.

The upper insulating layer 166 may be disposed on the substrate insulating layer 165. The upper insulating layer 166 may include a different material from the substrate insulating layer 165 and may conformally cover the circuit elements and the substrate insulating layer 165 above the exposed substrate 101 so as to have a thickness greater than that of the substrate insulating layer 165. The upper insulating layer 166 may include silicon nitride, silicon oxynitride, or a low-k dielectric material. Since the upper insulating layer 166 is formed of a different material from the substrate insulating layer 165, the upper insulating layer 166 may function as an etch-stop layer during a process.

The substrate insulating layer 165 and the upper insulating layer 166 may have respective functions thereof and may include different materials, thereby protecting the lower circuit elements and the semiconductor substrate 101. A total thickness of the substrate insulating layer 165 and the upper insulating layer 166 may be in the range of 30 nm to 50 nm, and preferably in the range of 30 nm to 40 nm. In addition, the upper insulating layer 166 may have the greatest thickness within the thickness.

The interlayer insulating layer 160 may be provided on the substrate 101. The interlayer insulating layer 160 may cover the gate electrodes 125 of the transfer transistor TG, the selection transistor SEL, the reset transistor RX and the source follower transistors SF1 and SF2 on the upper insulating layer 166, and the exposed substrate 101 therebetween. The interlayer insulating layer 160 may include a single film of at least one of a silicon oxide film (SiO), a silicon nitride film (SiN), a silicon nitride film (SiON), or a porous low-k dielectric film, or a multifilm structure thereof.

At least one intermetallic insulating layer 163 may be provided on the interlayer insulating layer 160. The intermetallic insulating layers 163 may include a single film structure of at least one of a silicon oxide (SiO), a silicon nitride (SiN), a silicon oxynitride (SiON), and a porous insulating layer, or a multifilm structure. Upper interconnection lines 158 and contact vias may be disposed between the intermetallic insulating layers 163. The contact vias may include a metal such as tungsten (W), aluminum (Al), or copper (Cu), and tungsten may be preferably applied thereto.

The contact vias may have a pillar shape and may have an inclined side surface in which a width decreases toward the substrate 101.

The first structure L1 may include first bonding structures 166 and 169.

The first bonding structures 166 and 169 includes a first bonding insulating layer 166 and first bonding pads 169, and may perform hybrid bonding with the second bonding structure of the second structure L2.

The second structure L2 may include a logic substrate 401, and may include a second interconnection structure 430 connected to second circuit elements 420, a second bonding structure 440 on the second interconnection structure 430, and a logic insulating layer 443 covering the second circuit elements 420 and the second interconnection structure 430 on the logic substrate 401. The second bonding structures 466 and 469 may be connected to the second interconnection structure 430 on the second interconnection structure 430. The second bonding structures 466 and 469 may include a metal material such as copper (Cu). The second bonding structures 466 and 469 may include a bonding pad 469 to be physically bonded to the first bonding pads 169 and may also provide an electrical connection path. The second bonding insulating layer 466 may be bonded to the first bonding insulating layer 166 to provide a hybrid bond. The logic insulating layer 440 may cover the second circuit elements 420 and the third interconnection structure 430.

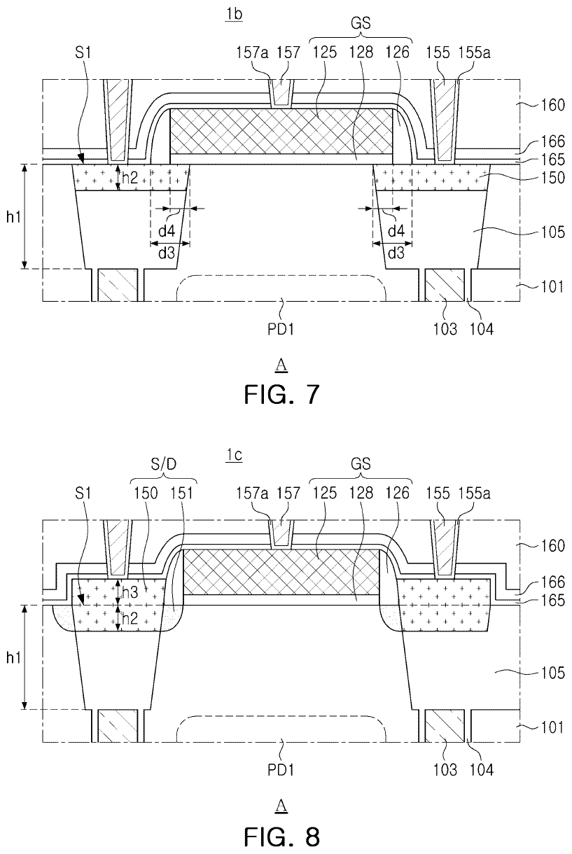

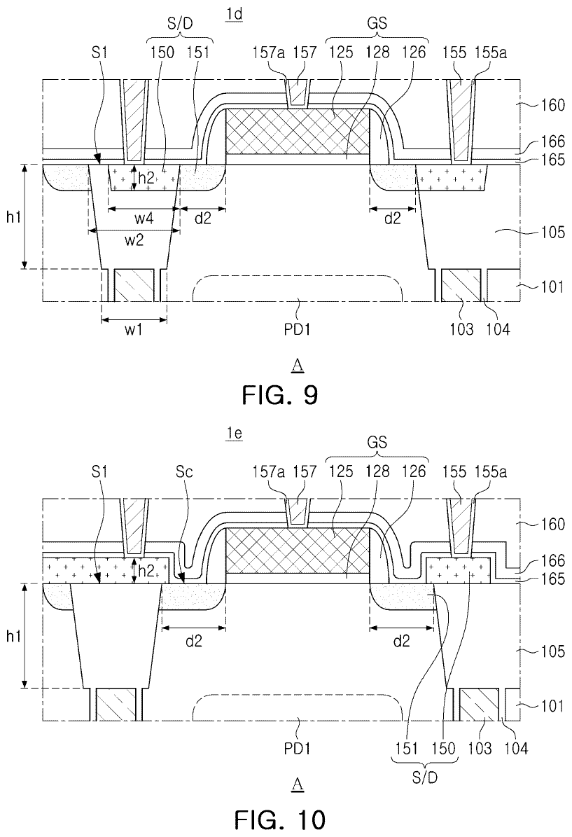

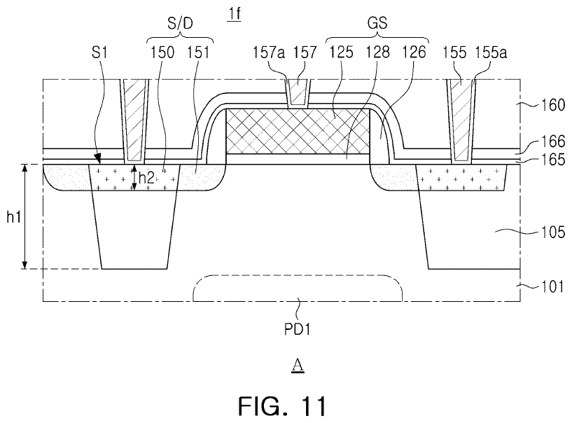

Hereinafter, example embodiments of the present disclosure will be described with reference to FIG. 6, FIG. 7, FIG. 8, FIG. 9, FIG. 10 and FIG. 11. FIG. 6, FIG. 7, FIG. 8, FIG. 9, FIG. 10 and FIG. 11 are enlarged views of pixel regions of an image sensor according to example embodiments of the present disclosure, which are enlarged views of region “A” of FIG. 5.

Referring to FIG. 6, an image sensor 1a of example embodiments of the present disclosure may be the same as the image sensor 1 of FIG. 5, except for the shape of the source/drain region (S/D) of the source follower transistors SF1 and SF2.

Specifically, the source/drain region (S/D) of the source follower transistors SF1 and SF2 may be implemented only with the conductive layer 150 without the conductive region 151.

The conductive layer 150 may be a structure which protrudes into the PD isolation pattern IS, specifically, into the second isolation pattern 105 adjacent to the gate pattern GS and fills the second isolation pattern 105, and in which an upper surface thereof may be coplanar with one surface S1 of the substrate 101.

The conductive layer 150 may have a lower surface in contact with the second isolation pattern 105 and may have at least a portion of a side surface in contact with the substrate 101. Specifically, the conductive layer 150 may be disposed to be in contact with the channel region of the source follower transistors SF1 and SF2.

The gate spacer 126 of the gate pattern GS may be disposed on the upper surface of the conductive layer 150, and the lower surface of the gate spacer 126 may be in direct contact with the upper surface of the conductive layer 150.

Accordingly, the gate spacer 126 and the conductive layer 150 may overlap one another by a second distance d2 in the Z-direction.

The shape and material of the conductive layer 150 may be the same as those in FIGS. 3 to 5.

Referring to FIG. 7, an image sensor 1b of the example embodiment of the present disclosure may be the same as the image sensor 1 of FIG. 5, except for the shape of the source/drain region (S/D) of the source follower transistors SF1 and SF2. Specifically, the source/drain region (S/D) of the source follower transistors SF1 and SF2 may be implemented only with the conductive layer 150 without the conductive region 151.

The conductive layer 150 may be a structure which protrudes into the PD isolation pattern IS, specifically, into the second isolation pattern 105 adjacent to the gate pattern GS and is buried in the second isolation pattern 105, and in which an upper surface thereof is coplanar with one surface S1 of the substrate 101. The gate spacer 126 may be disposed on the conductive layer 150, and a portion of the gate electrode 125 may also be disposed on the conductive layer 150.

For example, the gate pattern GS and the conductive layer 150 may overlap one another by a third distance d3 in the vertical direction, and the gate electrode 125 and the conductive layer 150 may be understood as overlapping one another by a fourth distance d4.

In this case, the fourth distance d4 may be smaller than ½ of the third distance d3, but the present disclosure is not limited thereto. Even in this case, since a side surface of the conductive layer 150 has a continuous inclination with the side surface of the second isolation pattern 105, it may be understood that the conductive layer 150 exists only within the second isolation pattern 105.

That is, the overlapping of the conductive layer 150 and the gate electrode 125 may be achieved by allowing the gate electrode 125 to extend in the horizontal direction and covering the second isolation pattern 105.

The shape and material of the conductive layer 150 may be the same as those in FIGS. 3 to 5.

Referring to FIG. 8, an image sensor 1c of the example embodiment of the present disclosure may be the same as the image sensor 1 of FIG. 5, except for the shape of the source/drain region (S/D) of the source follower transistors SF1 and SF2.

Specifically, the source/drain region (S/D) of the source follower transistors SF1 and SF2 may have an upper surface of the conductive layer 150 on a higher level than one surface S1 of the substrate 101.

The conductive layer 150 may be a structure which protrudes into the PD isolation pattern IS, specifically, into the second isolation pattern 105 adjacent to the gate pattern GS, and has a first partial depth h2 buried in the second isolation pattern 105, and in which a portion thereof protrudes upwardly from one surface S1 of the substrate 101 and has a second partial depth h3.

The first partial depth h2 may be greater than the second partial depth h3, but the present disclosure is not limited thereto. Accordingly, a depth of the conductive layer 150 may be greater than the conductive layer 150 of FIG. 5.

A side surface of an upper region having the second partial depth h3 of the conductive layer 150 may be in contact with the gate spacer 126, and a side surface of a lower region having the first partial depth h2 may be in contact with the conductive region 151, and the side surfaces of the upper region and the lower region may have a continuous inclination, but the present disclosure is not limited thereto.

In this case, the second partial depth h3 of the upper region of the conductive layer 150 may be greater than a thickness of the gate insulating layer 128, and may be smaller than a thickness of the gate electrode 125. A level of the upper surface of the conductive layer 150 may be disposed lower than a level of an upper surface of the gate electrode 125.

The material of the conductive layer 150 may be the same as that of FIGS. 3 to 5.

Referring to FIG. 9, an image sensor 1d of example embodiments of the present disclosure may be the same as the image sensor 1 of FIG. 5, except for the shape of the source/drain region (S/D) of the source follower transistors SF1 and SF2.

Specifically, in the source/drain region (S/D) of the source follower transistors SF1 and SF2, a width W3 of an upper portion of the conductive layer 150 may be smaller than a width W2 of an upper surface of the second isolation pattern 105. In the source follower transistors SF1 and SF2 having the conductive layer 150 filling the second isolation pattern 105, the conductive layer 150 of the source/drain region (S/D) is not shared with the source/drain region (S/D) of the source follower transistors SF1 and SF2 adjacent to one another.

When the upper surface of the second isolation pattern 105 on which the conductive layer 150 is disposed has the second width W2, the conductive layer 150 may have a fourth width W4 from one side in contact with the conductive region 151 of the corresponding source follower transistors SF1 and SF2, and the fourth width W4 may be smaller than the second width W2. Accordingly, the upper surface of the conductive layer 150 and the upper surface of the second isolation pattern 105 may form a coplanar surface and may be disposed in a row.

The material of the conductive layer 150 may be the same as that of FIGS. 3 to 5.

Referring to FIG. 10, an image sensor le of example embodiments of the present disclosure may be the same as the image sensor 1 of FIG. 5, except for the shape of the source/drain region (S/D) of the source follower transistors SF1 and SF2.

Specifically, the source/drain region (S/D) of the source follower transistors SF1 and SF2 may have a width of the conductive layer 150 greater than a width of the second isolation pattern 105. The conductive layer 150 is disposed on the second isolation pattern 105 and does not fill the second isolation pattern 105. Accordingly, a lower surface of the conductive layer 150 may be in contact with the upper surface of the second isolation pattern 105, and an upper surface thereof may be disposed on a higher level than one surface S1 of the substrate 101.

In this case, the conductive layer 150 may cover the entire width of the second isolation pattern 105 and may extend toward the gate electrode 125 of the source follower transistors SF1 and SF2. Accordingly, at least a portion of the conductive layer 150 may overlap the conductive region 151 vertically.

The conductive region 151 does not horizontally overlap the gate electrode 125, and a portion thereof may overlap the gate spacer 126 vertically, and the remainder thereof may overlap the conductive layer 150 vertically. In this case, side surfaces of the conductive layer 150 and the gate spacer 126 may be spaced apart from one another, so that a portion of the conductive region 151 may be exposed between the conductive layer 150 and the gate spacer 126, but the present disclosure is not limited thereto.

However, in order to secure a maximum area of the gate electrode 125, the gate electrode 125 may be expanded so that the side surfaces of the gate spacer 126 and the conductive layer 150 are in contact with one another.

In this manner, the conductive layer 150 may be formed so as to overlap the second isolation pattern 105 without filling the second isolation pattern 105, and may be disposed in a state of being electrically conductive by contacting the conductive region 151 at an interface Sc vertically instead of the side surface thereof.

The material of the conductive layer 150 may be the same as that of FIGS. 3 to 5.

Referring to FIG. 11, an image sensor 1f of example embodiments of the present disclosure may be the same as that of FIG. 5, except for the shape of the PD isolation pattern IS.

Specifically, a trench separation film may not be disposed in a lower portion of the second isolation pattern 105 overlapping the conductive layer 150. This may form a source/drain region (S/D) by stacking a conductive layer 150 different from the substrate 101 not only on the second isolation pattern 105 on the first isolation pattern 103 defining each pixel region PA, but also on the second isolation pattern 105 within the pixel region PA.

The shape and material of the conductive layer 150 may be the same as those in FIGS. 3 to 5.

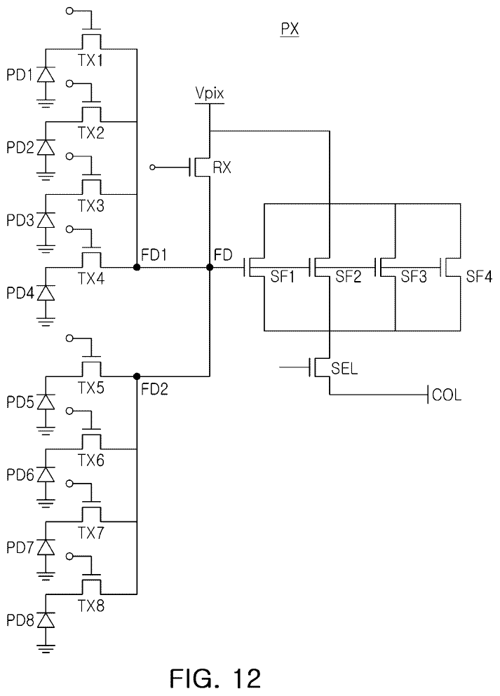

Hereinafter, pixel regions in which pixel circuits different from those of FIG. 2 are implemented will be described with reference to FIGS. 12 to 14.

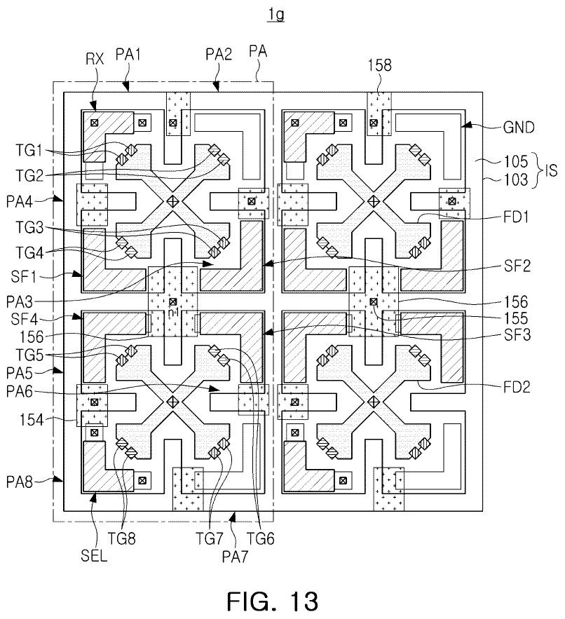

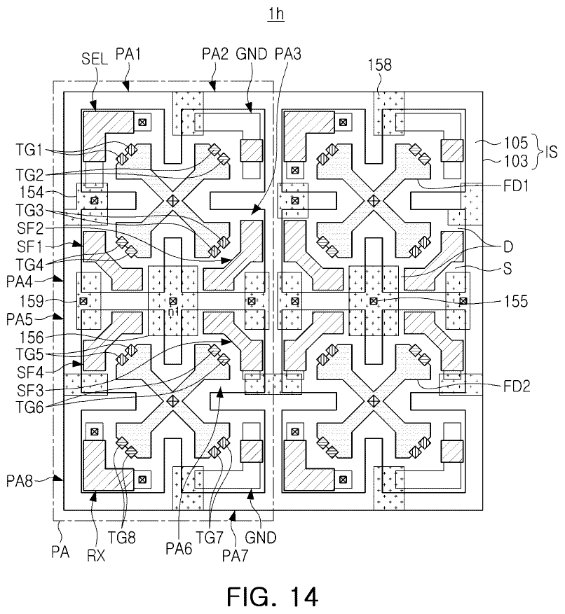

FIG. 12 is a circuit diagram simply illustrating a pixel circuit according to example embodiments of the present disclosure, and FIGS. 13 and 14 are layout diagrams of an image sensor according to example embodiments of the present disclosure.

Referring to FIG. 12, a pixel circuit PX according to example embodiments of the present disclosure may include eight transfer transistors TX1 to TX8 and eight photodiodes PD1 to PD8 which are respectively connected, and may include a reset transistor RX, a selection transistor SEL, and four source follower transistors SF1 to SF4. In addition, the pixel circuit PX may include a floating diffusion region FD in which the charges generated by the photodiodes PD1 to PD8 are accumulated.

One floating diffusion region FD may be allocated to each of the four transfer transistors (TX1 to TX4/TX5 to TX8), so that two floating diffusion regions FD1 and FD2 may be included, and the two floating diffusion regions FD1 and FD2 may be connected to one another.

In this example embodiment, a voltage change accumulated in the integrated floating diffusion region FD may be amplified and output to the column lines COL by including the four source follower transistors SF1 to SF4. For this purpose, the four source follower transistors SF1 to SF4 may be connected in parallel with one another, and may include gate electrodes having the largest area, respectively, thereby minimizing noise.

The reset transistor RX may be controlled by a reset control signal, and the selection transistor SEL may be controlled by a selection control signal. The first to eighth transfer transistors (TX1 to TX4/TX5 to TX8) may be controlled by a first or second bias voltage, which is a transmission signal.

Each of the pixels PX may be structured as one pixel region PA, and one pixel region PA may include eight sub-pixel regions PA1 to PA8, as illustrated in FIG. 13. The eight sub-pixel regions PA1 to PA8 may be arranged in a 4×2 array. Among the eight sub-pixel regions PA1 to PA8, the first to fourth sub-pixel regions PA1 to PA4 may be arranged in a 2×2 array, and may include a first common floating diffusion region FD1 in a center thereof. Specifically, the first sub-pixel region PA1 may include a first photodiode PD1, at least a portion of the common floating diffusion region FD1, and a first transfer transistor TX1 having a first transfer gate TG1. In the first pixel region PA1, the first photodiode PD1 may be connected to the common floating diffusion region FD via the first transfer transistor TX1. Similarly, the second to fourth photodiodes PD2 to PD4 of the second to fourth sub-pixel regions PA2 to PA4 may be connected to the first common floating diffusion region FD1 via the second to fourth transfer transistors TX2 to TX4 including the second to fourth transfer gates TG2 to TG4, respectively.

The fifth to eighth sub-pixel regions PA5 to PA8 of the eight sub-pixel regions PA1 to PA8 may be arranged in a 2×2 array and may include a second common floating diffusion region FD2 in the center thereof. The fifth sub-pixel region PA5 may include a fifth photodiode PD5, at least a portion of a common floating diffusion region FD, and a fifth transfer transistor TX5 having a fifth transfer gate TG5. In the fifth pixel region PA5, the fifth photodiode PD5 may be connected to the common floating diffusion region FD via the fifth transfer transistor TX5. Similarly, the sixth to eighth photodiodes PD6 to PD8 of the sixth to eighth sub-pixel regions PA6 to PA8 may be connected to the second common floating diffusion region FD2 via the sixth to eighth transfer transistors TX6 to TX8 including the sixth to eighth transfer gates TG6 to TG8, respectively.

In the four sub-pixel regions PA1 to PA4 and PA5 to PA8 adjacent to one another, each of the common floating diffusion regions FD1 and FD2 isa single structure in which the common floating diffusion regions FD1 and FD2 may be connected to one another, and may be understood as a structure expanded from the center of the four sub-pixel regions PA1 to PA4 and PA5 to PA8 to each of the four sub-pixel regions PA1 to PA4 and PA5 to PA8. For example, as illustrated in FIG. 13, four bar-type regions passing through center regions of the four sub-pixel regions PA1 to PA4 and PA5 to PA8 and extending to each of the four sub-pixel regions PA1 to PA4 and PA5 to PA8 may be included, and expanded regions may be included in each end thereof. The common floating diffusion regions FD1 and FD2 connected to the four sub-pixel regions PA1 to PA4 and PA5 to PA8 may be connected to one another through circuit interconnection lines.

The eight sub-pixel regions PA1 to PA8 adjacent to one another may share a pixel circuit, and the shared pixel circuit may include ground regions GND, a reset transistor RX, first to fourth source follower transistors SF1 to SF4 and a selection transistor SEL.

For example, each of the eight sub-pixel regions PA1 to PA8 may further include one transistor or a ground region GND in addition to the transfer transistors TX1 to TX8. Four of the transistors included in the eight sub-pixel regions PA1 to PA8 may be connected in parallel to one another to provide the first to fourth source follower transistors SF1 to SF4, and one thereof may be provided as a selection transistor SEL, another may provide a reset transistor RX, and the remainder may provide a ground region GND.

The first to fourth source follower transistors SF1 to SF4 connected in parallel to one another are disposed in sub-pixel regions PA3, PA4, PA5 and PA6 adjacent to one another and may be arranged symmetrically with respect to the center n1 of the pixel region PA.

For example, the transistors of the third, fourth, fifth, and sixth sub-pixels PA3, PA4, PA5 and PA6 may function as source follower transistors SF1 to SF4. Drain regions of the four source follower transistors SF1 to SF4 may be densely packed toward the center of a sub-region, and a common conductive layer 156 connecting the drain regions simultaneously may be disposed.

Specifically, the drain regions of the four source follower transistors SF1 to SF4 may include the conductive regions 151 of FIGS. 3 to 5, respectively, and the common conductive layer 156 at least partially in contact with the conductive region 151 may be disposed on the PD isolation pattern IS. There is.

The common conductive layer 156 may fill at least a portion of the second isolation pattern 105 as illustrated in FIG. 5 and may simultaneously contact four conductive regions 151 on a side surface thereof, but the present disclosure is not limited thereto, and various structures of the conductive layers 156 of FIGS. 6 to 11 may be applied thereto.

In this manner, the drain regions of the four adjacent source follower transistors SF1 to SF4 may be connected to the common conductive layer 156, and may thus be driven by one contact plug 155 in contact with the common conductive layer 156.

In FIG. 13, the conductive layer 156 is illustrated as also performing a function of interconnection lines for connecting the drain regions, but may be understood as an expansion of the drain region, or an arrangement on the second isolation pattern 105 of the drain region, which may induce an area expansion of the gate electrode 125 of the source follower transistors SF1 to SF4. Accordingly, the source regions of the source follower transistors SF1 to SF4 may also include a conductive layer 154 connected to the second isolation pattern 105.

In FIG. 13, the first conductive layer 154 connecting a source region of the source follower transistors SF1 to SF4 and a drain of the selection transistor SEL and a second conductive layer 158 connecting a ground region of an adjacent pixel region and a ground region of the pixel region may be disposed.

In addition to the first and second conductive layers 150, conductive layers 150 that may function as circuit interconnection lines in connection points in the pixel circuit of FIG. 12 may be further disposed.

The first and second conductive layers 150 may also be disposed on the second isolation pattern 105, thereby securing the area of the gate electrode 125 of the circuit element.

Meanwhile, referring to FIG. 14, in the pixel circuit of FIG. 12, four source follower transistors SF1 to SF4 may be disposed in a bent form, and may have a structure bent in a corner of the PD isolation pattern IS.

Each source follower transistor SF1 to SF4 may include a region extending in the X-direction, and bent in the corner and extending in the Y-direction. Each source follower transistor SF1 to SF4 may include a drain region D in both ends and may include a source region S in the corner.

The gate pattern GS may be disposed between the drain region D and the source region S in both ends. Accordingly, the shape of the gate electrode 125 may have a dumbbell shape disposed diagonally as in FIG. 14, but the present disclosure is not limited thereto.

In this manner, drain regions D of one end of the source follower transistors SF1 to SF4 may be disposed symmetrically with respect to the center nl of the pixel region, and the conductive layer 156 connecting the drain regions D may be disposed.

A source conductive layer 159 connecting adjacent source regions S of the source follower transistors SF1 to SF4 may be further disposed, and a connection conductive layer 154 connecting the drain region of the reset transistor RX and the drain region of the source follower transistors SF1 to SF4 may be further included.

In this manner, when the conductive layers 154 and 159 are further disposed, interconnection lines may be drastically reduced, and the number of contact plugs 155 and 157 may also be reduced.

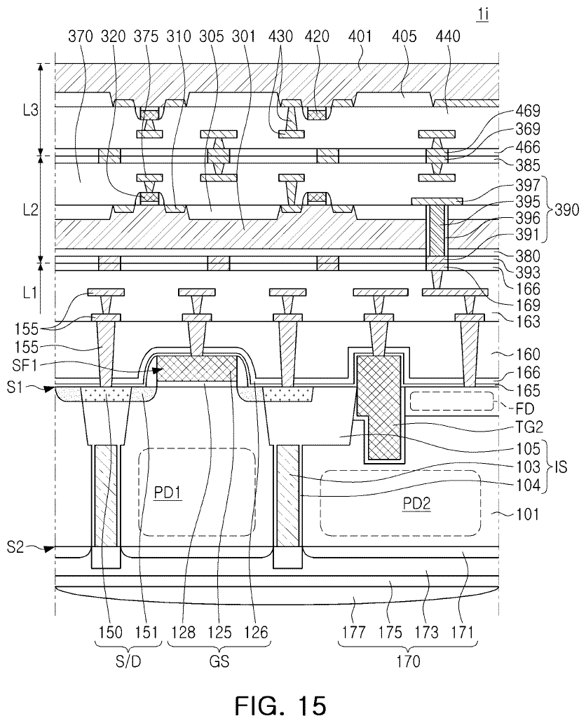

FIG. 15 illustrates a cross-section of an image sensor according to example embodiments of the present disclosure.

Referring to FIG. 15, an image sensor 10i may include a third structure L3 forming a logic circuit 20, a second structure L2 formed below the third structure L3 and forming a pixel array 10, and a first structure L1 therebelow.

The image sensor 10i may include a first structure L1 including a first substrate 101, a second structure L2 including a second substrate 301, and a third structure L3 including a third substrate 401. The third structure L3 may be a logic chip including a logic circuit 20, and the second and first structures L1 and L2 may be image sensor structures including a plurality of pixels PX. The first structure L1 may include a source follower transistor SF and a transfer gate TG, and the second structure L2 may include the remaining transistors except for the source follower transistor SF and the transfer gates TG.

The first structure L1 may include a source follower transistor SF, a transfer gates TG1 to TG4, a common floating diffusion region FD, and photodiodes PD1, PD2, PD3, and PD4, among the structures of the first substrate 101 described in FIGS. 1 to 5, and may include first bonding structures 166 and 169 in an upper portion. The first structure L1 may include an optical unit 170 on the other surface of the first substrate 101, and the description thereof may be the same as that of FIG. 4.

The second structure L2 may include a second substrate 301 having a lower surface facing the first structure L1 and an upper surface opposite to the lower surface, an element separation film 305 defining an active region 310 within the second substrate 301, circuit elements 320 on an upper surface of the second substrate 301, an interconnection region 375 connected to the circuit elements 320, second lower bonding structures 390 and 393 on a lower surface of the second substrate 301, a second upper bonding structure 385 on the upper surface of the second substrate 301, a second lower insulating layer 380 on the lower surface of the second substrate 301, and a second upper insulating layer 370 on the upper surface of the second substrate 301.

In the second circuit elements 320, transistors excluding the transfer gates TG1, TG2, TG3, and TG4 may be arranged. The interconnection region 375 may be disposed between the second substrate 301 and the third structure L3. The interconnection region 375 may apply an electrical signal to the second circuit elements 320. The second upper bonding structures 385 and 369 may be a structure for bonding with the third structure L3. The second upper bonding structures 385 and 369 may include a metal material such as copper (Cu), but may be implemented as a bonding insulating layer.

The second lower insulating layer 380 may include a bonding insulating layer 393 having a predetermined thickness from a lower surface. The bonding insulating layer 393 may be a layer for dielectric-dielectric bonding with the bonding insulating layer 166 of the first structure L1.

The second lower bonding structure 390 may be a structure for bonding with the first structure L1. The second lower bonding structure 390 may include a third bonding pad 391 on the lower surface of the second substrate 301, a landing structure 397 disposed on the upper surface of the second substrate 301, a third bonding via 395 disposed between the third bonding pad 391 and the landing structure 397, and a side insulating layer 396 between the second substrate 301 and the third bonding via 395. The third bonding pad 391 may include a metal material such as copper (Cu), and the third bonding via 395 may include a metal material such as copper (Cu), tungsten (W) and the like. The third bonding pad 391 may include the same metal material as the third bonding via 395, but the present disclosure is not limited thereto.

The third structure L3 may include a third substrate 401, and may further include a third interconnection structure 430 connected to third circuit elements 420, a third bonding structure 469 and 466 on the third interconnection structure 430, and a logic insulating layer 440 covering the third circuit elements 420 and the third interconnection structure 430 on the third substrate 401. The third bonding structures 469 and 466 may be connected to the third interconnection structure 430 on the interconnection structure 430. The third bonding structures 469 and 466 may include a metal material such as copper (Cu). The third bonding structures 469 and 466 may include a bonding pad 469 and may also provide an electrical connection path. The logic insulating layer 440 may cover the third circuit elements 420 and the third interconnection structure 430 and may cover portions of the third bonding structures 469 and 466 at the same time.

In this manner, the image sensor chip including a pixel array may be separated into two structures L1 and L2, and hybrid bonding by the bonding structure 390 may be performed between the structures L1 and L2 to electrically connect the structures L1 and L2, so that an image sensor li may be implemented by hybrid bonding of three structures L1, L2 and L3.

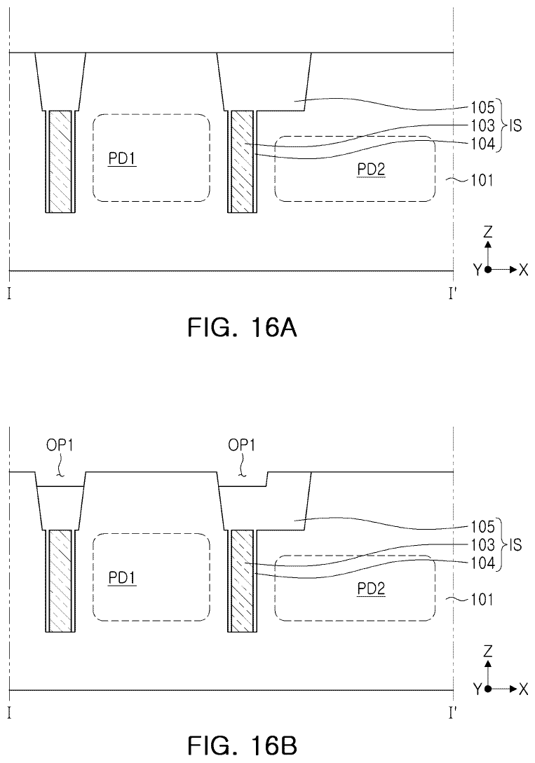

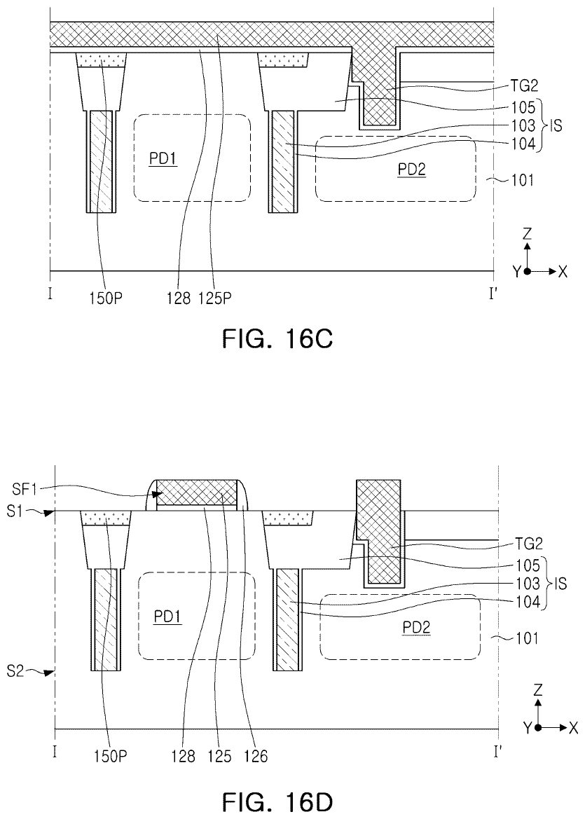

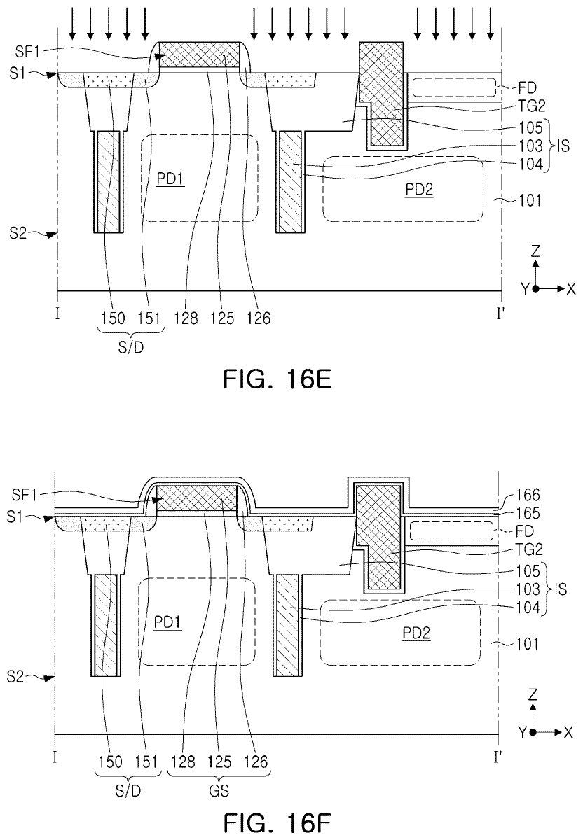

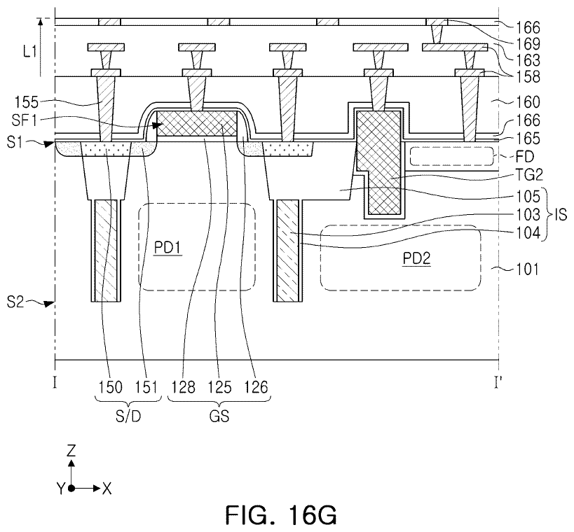

Hereinafter, a method of manufacturing an image sensor of example embodiments of the present disclosure will be described with reference to FIGS. 16A to 16G. FIGS. 16A to 16F are cross-sectional views illustrating a method of manufacturing a pixel array of an image sensor 1 of FIG. 4.

Referring to FIG. 16A, a substrate 101 may be prepared, and a second isolation pattern 105 and a first isolation pattern 103 may be formed from one surface S1 of the substrate 101.

Specifically, photodiodes PD1, PD2, PD3, and PD4 may be formed within the substrate 101, and the second isolation pattern 105 defining an active region ACT on one surface S1 of the substrate 101 may be formed by forming a trench and filling the trench. In this case, an oxide film may be formed on an inner wall of the trench, and then a nitride film may be formed as a liner.

A portion of the second isolation pattern 105 may be opened, and a deep trench for forming a first isolation pattern 103 may be formed, and the deep trench may be formed in a grid shape for partitioning each sub-pixel region PA1 to PA4. In addition, the deep trench may be formed in the X-direction and the Y-direction to form a second-first separation film 103a and a second-second separation film 103b together, among the trench separation films 103.

That is, after forming the deep trench from a bottom surface of the second isolation pattern 105, a trench liner 104 may be formed, and a first isolation pattern 103 as insulating material and a conductive material may be formed in a center thereof. The conductive material may be polysilicon. Next, an element isolation insulating film may be formed to cover the trench.

In this case, the insulating material may be over-deposited and then planarized until one surface of the substrate is exposed, thus forming a second isolation pattern 105.

Referring to FIG. 16B, a portion of the second isolation pattern 105 in a region in which the source follower transistors SF1 and SF2 are disposed may be removed to form a first opening OP1 corresponding to the conductive layer 150.

In this case, the first opening OP1 may be formed by etching the second isolation pattern 105 by a second width W2 and a second depth d2, and may have different depths depending on interlayer etching selectivity of the second isolation pattern 105, but may be formed to have the second depth d2 as a whole.

As illustrated in FIG. 16C, the first opening OP1 may be filled by depositing a preliminary conductive material.

First, cleaning may be performed to remove a natural oxide film. In this case, cleaning may be performed through HF solution or dry cleaning. After cleaning, the first opening OP1 may be filled, and a preliminary conductive material may be over-deposited to cover one surface S1 of the substrate.

A preliminary conductive material 150P may be formed by depositing polysilicon or epitaxially growing single crystal silicon.

The preliminary conductive material may be planarized to form a preliminary conductive layer 150P filling the first opening OP1. In this case, the planarization process may be performed through chemical mechanical polishing (CMP) and etch-back may be performed, but the present disclosure is not limited thereto. According to such a planarization process, an upper surface of the conductive layer 150P may have a flat coplanar surface with one surface S1 of the substrate 101.

Next, as illustrated in FIG. 16D, the transfer transistors TG1, TG2, TG3, and TG4 and the gate pattern GS of the transistors may be formed. First, an opening may be formed to open a region corresponding to the transfer transistors TG1 to TG4, and a depth of the opening may vertically extend into the substrate 101 to be close to the photodiodes PD1, PD2, PD3, and PD4.

A gate insulating layer 128 may be formed on an inner surface of the opening and on one surface S1 of the substrate 101. In an operation of forming the gate insulating layer 128, after conducting a cleaning process as a preprocessing to remove a surface oxide film, a silicon oxide film, or the like, may be deposited and formed as the gate insulating layer 128. In this case, the gate insulating layer 128 may be formed entirely in a region in which the transistors are formed in one surface S1 of the substrate 101, specifically, a remaining region which is not the second isolation pattern 105. The opening may be filled and a conductive layer 125P may be formed. In this case, the conductive layer 125P may be formed by stacking polysilicon, and the like, and may be formed to have conductivity by performing ion-injection after deposition of polysilicon. In this case, the conductive layer 125P may be over-deposited on the one surface S1 of the substrate 101 as a whole so that the conductive layers 125P of other transistors may be formed at the same time.

The conductive layer 125P may be patterned to simultaneously form the transfer gates TG1, TG2, TG3, and TG4 and the gate electrode layers 125 of other transistors. In this case, the gate insulating layer 128 may remain in a lower portion of each gate electrode layer 125, and a gate spacer 126 may be formed on the side surface of the gate electrode 125.

Referring to FIG. 16E, the first conductivity type impurity may be ion-injected onto the preliminary conductive layer 150P and the gate spacer 125.

For example, as the first conductivity type impurity, impurities such as P, As and the like, may be injected. In this case, the first conductivity type impurity may also be injected into the floating diffusion region FD, and injection concentrations thereof may be different from one another, but the present disclosure is not limited thereto. In addition, a ground region may also be formed by injecting impurities of different conductivity types.

Accordingly, conductive regions 151 may be formed below the gate spacer 126, and the source/drain region (S/D) of FIG. 4 may be formed by injecting the first conductivity type impurity into the conductive layer 150.

As illustrated in FIG. 16F, after forming the substrate insulating layer 165, annealing may be performed to advance activation, i.e., diffusion, of respective injected impurity ions.

In addition, after the annealing, a nitride film, which is an upper insulating layer 166, may be formed to protect the elements. In this case, the substrate insulating layer 165 and the upper insulating layer 166 may be formed conformally according to the shape of each element.

As illustrated in FIG. 16G, after forming the interlayer insulating layer 160, contact plugs 155 and 157 penetrating through the interlayer insulating layer 160 and contacting each element may be formed.

The contact plugs 155 and 157 may be formed by forming a via hole, forming diffusion barriers 155a and 157a, and then performing deposition and planarization to bury a metal layer in the via hole. The diffusion barriers 155a and 157a may be formed of TiN, TaN, or the like, and the metal layer may include a conductive material such as W, Al, or Cu. Via holes may be formed to reach the gate electrode layer 125 and may be formed to open the conductive layer 150.

Then, upper interconnection structures 158 may be formed, and bonding structures 166 and 169 may be formed, and as illustrated in FIG. 4, a second structure L2 may be formed in an upper portion, and an optical unit 170 may be formed on the other surface S2 of the substrate 101, thereby forming the image sensor 1 of FIG. 4.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. An image sensor, comprising:
a substrate including pixel regions including each photodiode;
a floating diffusion region disposed in each of the pixel regions and configured to store charges transferred from the photodiode, on one surface of the substrate;
circuit elements transmitting a photoelectric signal according to the charges of the floating diffusion region; and
an upper isolation pattern defining the floating diffusion region and the circuit elements on the one surface of the substrate,
wherein at least one of the circuit elements includes:
a gate pattern disposed on the one surface of the substrate; and
a source/drain region disposed on both side surfaces of the gate pattern, and
wherein at least one of the source/drain regions includes a conductive layer disposed on the upper isolation pattern, contacting the substrate below the gate pattern, and including a material different from a material of the substrate.

2. The image sensor of claim 1, wherein the conductive layer includes polysilicon including a first conductivity type impurity.

3. The image sensor of claim 1, wherein:
the image sensor includes a lower isolation pattern separating the photodiode within the substrate,
the upper isolation pattern is disposed on the lower isolation pattern, and
the conductive layer overlaps at least a portion of the lower isolation pattern in a vertical direction.

4. The image sensor of claim 1, wherein:
the conductive layer includes an upper surface and a lower surface, and the upper surface of the conductive layer is coplanar with the one surface of the substrate, and
the lower surface of the conductive layer is disposed on a higher level than a level of a lower surface of the upper isolation pattern.

5. The image sensor of claim 1, wherein the conductive layer extends downwardly from an upper surface of the upper isolation pattern to bury the upper isolation pattern.

6. The image sensor of claim 1, wherein the gate pattern includes:
a gate insulating layer on the one surface of the substrate;
a gate electrode on the gate insulating layer; and
gate spacers on both sides of the gate electrode, and
wherein in a plane, the conductive layer is spaced apart from the gate electrode.

7. The image sensor of claim 6, wherein the source/drain region further includes a conductive region downward from the one surface of the substrate between the gate electrode and the conductive layer.

8. The image sensor of claim 7, wherein the conductive region is defined as a region in which the substrate is doped with the first conductivity type impurity.

9. The image sensor of claim 7, wherein:
the circuit elements are disposed on both sides of the conductive layer, and
the conductive layer is in contact with the conductive region of each of the circuit elements.

10. The image sensor of claim 9, wherein:
the image sensor further includes a contact plug electrically connected to the circuit elements, and
the contact plug is in contact with the upper surface of the conductive layer.

11. The image sensor of claim 7, wherein at least one of the circuit elements includes a source follower buffer amplifier amplifying the charges of the floating diffusion region.

12. The image sensor of claim 11, wherein the gate pattern of the source follower buffer amplifier has a larger area than a gate pattern of the other circuit elements.

13. The image sensor of claim 7, wherein:
the conductive layer includes a side surface between an upper surface and a lower surface, and
the side surface in contact with the conductive region, has a continuous inclination with a side surface of the upper isolation pattern.

14. The image sensor of claim 1, wherein the conductive layer has an upper surface disposed on a higher level than a level of the one surface of the substrate.

15. The image sensor of claim 14, wherein at least a portion of a lower surface of the conductive layer is positioned at substantially a same level as a level of the one surface of the substrate.

16. An image sensor, comprising:
a substrate including pixel regions including each photodiode;
a lower isolation pattern defining the pixel regions within the substrate;
a floating diffusion region configured to store charges transferred from the photodiode, on one surface of the substrate;
a source follower transistor including a gate pattern disposed adjacently to the lower isolation pattern and source/drain regions disposed on both sides of the gate pattern, and configured to transmit a signal by amplifying the charges of the floating diffusion region; and
an upper isolation pattern disposed on the lower isolation pattern on the one surface of the substrate and adjacent to the gate pattern of the source follower transistor,
wherein at least one of the source/drain regions of the source follower transistor includes a semiconductor conductive layer disposed on the adjacent upper isolation pattern, overlapping the lower isolation pattern in a vertical direction, and including a material different from a material of the substrate.

17. The image sensor of claim 16, wherein at least one of the source/drain regions of the source follower transistor further includes a conductive region doped with a first conductivity type impurity from the one surface of the substrate below the gate pattern, and in contact with the semiconductor conductive layer.

18. The image sensor of claim 17, wherein the semiconductor conductive layer protrudes inwardly from an upper surface of the upper isolation pattern and contacts the conductive region from a side surface.

19. The image sensor of claim 16, wherein:
the source follower transistors are respectively disposed in twopixel regions adjacent to one another, among the pixel regions, and
in a plane, the source follower transistors are disposed symmetrically with respect to the lower isolation pattern, and share the semiconductor conductive layer.

20. An image sensor, comprising:
a pixel array including a plurality of pixel regions arranged in a direction, parallel to one surface of a substrate, each of the plurality of pixel regions having at least one photodiode inside the substrate, a color filter disposed on the other surface of the substrate opposite to the one surface and at least one element disposed on the one surface; and
a logic circuit obtaining a pixel signal from the plurality of pixel regions,
wherein the pixel array includes:
a floating diffusion region disposed on each of the plurality of pixel regions, and configured to store charges transferred from the photodiode, on the one surface of the substrate;
circuit elements transmitting a photoelectric signal according to the charges of the floating diffusion region; and
an upper isolation pattern defining the floating diffusion region and the circuit elements on the one surface of the substrate,
wherein at least one of the circuit elements includes:
a gate pattern disposed on the one surface of the substrate; and
source/drain regions disposed on both side surfaces of the gate pattern, and
wherein at least one of the source/drain regions includes a conductive layer disposed on the upper isolation pattern, contacting the substrate below the gate pattern, and including a different material from the substrate.
